(19) United States
(12) Patent Application Publication
(10) Pub. No.: US 2014/0187687 A1
(43) Pub. Date: Jul. 3, 2014

(54) INSULATION MATERIALS, INSULATION COMPOSITION COMPRISING THE SAME, AND SUBSTRATE USING THE SAME

(71) Applicant: Samsung Electro-Mechanics Co., Ltd., Suwon (KR)

(72) Inventors: Soo Young JI, Hwasung (KR); Seung Hwan KIM, Suwon (KR); Suk Jin HAM, Seoul (KR)

(73) Assignee: Samsung Electro-Mechanics Co., Ltd., Suwon (KR)

(21) Appl. No.: 14/092,339

(22) Filed: Nov. 27, 2013

(30) Foreign Application Priority Data
Dec. 28, 2012 (KR) 10-2012-0157169

(51) Int. Cl. H05K 1/03

(52) U.S. Cl. CPC H05K 1/0373; H05K 1/0353
USPC 524/114; 525/326.5

(57) ABSTRACT

A soluble liquid crystal thermosetting oligomer containing polysilsesquioxane (POSS) includes a structure in which the POSS is combined with a main chain of a soluble liquid crystal thermosetting oligomer, an insulation composition comprising the same, and a substrate comprising and insulation layer using the insulation composition.

### CROSS-REFERENCE TO RELATED APPLICATIONS

This application claims the benefit under 35 U.S.C. Section 119 of Korean Patent Application Serial No. 10-2012-0157169, filed Dec. 28, 2012, which is hereby incorporated by reference in its entirety into this application.

### BACKGROUND OF THE INVENTION

1. Field of the Invention

The present invention relates to insulation materials, an insulation composition comprising the same, and a substrate using the same.

2. Description of the Related Art

With the advance of electronic devices, printed circuit boards are becoming lighter, thinner, and smaller day by day. In order to meet these requirements, wiring of printed circuits is becoming more complicated and densified.

Therefore, electrical, thermal, and mechanical stabilities of substrates serve as important factors. Among them, particularly, the coefficient of thermal expansion (CTE) is one of the important factors that affect reliability in manufacture of the substrates.

A printed circuit board chiefly comprises copper serving as circuit wiring and a polymer serving as an interlayer insulator. The CTE of the polymer constituting an insulating layer is much higher than that of copper. In order to overcome this difference, the CTE of the polymer constituting the insulation layer is reduced by impregnating the polymer into a woven glass fiber or adding an inorganic filler to the polymer.

Generally, as the amount of the inorganic filler is increased, the CTE of the insulating layer is reduced, but there are limitations in reducing the CTE of the insulating layer indefinitely due to manufacturing processes of the substrate.

Further, in order to meet the requirement for highly-densified fine patterns, surface roughness of the insulating layer is also considered as an important factor. The size of the inorganic filler added in order to secure the surface roughness is gradually reduced. However, as the size of the inorganic filler is reduced, the problem with the uniform dispersibility of the inorganic filler is on the rise and thus the problem that the nanoscale filler must be uniformly dispersed is also on the rise.

FIG. 1 shows a structure of a printed circuit board which comprises copper serving as circuit wiring and a polymer serving as an interlayer insulating layer. The CTE of the copper (Cu) circuit wiring is 10 to 20 ppm/° C., and the CTE al of a typical polymer material used in the insulating layer is 50 to 80 ppm/° C. Since the CTE of the polymer is greatly increased above a glass transition temperature (Tg, 150 to 200° C.), the CTE a2 at a high temperature reaches 150 to 180 ppm/° C.

Further, heat is rapidly supplied to a PCB for 3 to 5 seconds at a temperature of about 280° C. when mounting components such as semiconductors on the PCB. At this time, cracks of a circuit formed by plating and deformation of the substrate may occur due to a big difference in the CTE between the circuit and the insulating layer.

Ultimately, a polymer material of the insulating layer, which has a CTE equal to those of copper as circuit wiring and semiconductor chips placed on the substrate, is required. However, materials obtained by adjusting the kind and amount of a polymer and an inorganic filler, which constitute an existing insulating layer, are difficult to satisfy the requirement for complicated and highly-densified wirings of the printed circuits.

Meanwhile, there are two types of polymer composite insulation materials which are used in the insulating layer for printed circuit boards. One is a prepreg prepared by impregnating the polymer composite insulation material into a woven glass fabric or a woven glass cloth to semi-cure (B-stage) the polymer composite insulation material at a temperature below a glass transition temperature (Tg) of the material as in FIG. 2.

The other is a film manufactured using only the polymer composite insulation material without including the woven glass fabric as in FIG. 3. The latter method blends a polymer composite insulation material, an inorganic filler, a hardener, a solvent, additives, a curing accelerator, etc. at an optimal blending ratio and mixes, disperses, and casts the blend to form a film.

A main polymer composite insulation material, which forms an insulating layer of a conventional printed circuit board, is an epoxy resin. The CTE of the epoxy resin itself is about 70 to 100 ppm/° C. In order to reduce the CTE of the epoxy resin, the epoxy resin is impregnated into a woven glass fiber or a large amount of inorganic filler with a low CTE are added to an epoxy matrix to implement a low CTE as shown in FIG. 4.

The CTE of the epoxy resin is linearly reduced in proportion to the amount of the added fillers. However, when a large amount of the inorganic filler are added to reduce the CTE, dispersibility of the inorganic filler in the matrix is greatly deteriorated so that aggregation of the filler occurs and surface roughness of the printed circuit board is much increased. Further, since viscosity of the epoxy is rapidly increased, there are many difficulties in forming products. Especially, in case of a product having a multilayer structure such as an insulating film used in the printed circuit board, there are many cases where interlayer bonding is impossible.

For these limitations, it is needed to reduce the CTE of the epoxy resin itself and improve an effect at the same time by incorporating a critical amount of inorganic filler which can secure lamination proccessability. For example, the epoxy resins having different structures are mixed to reduce the CTE of the epoxy resin itself. At this time, the component and composition of each epoxy resin are important.

Further, since the CTE of the epoxy resin is greatly affected by the kind, size, and shape of the inorganic filler as well as the amount of the inorganic filler, miniaturization, that is, nanoscaling of the added inorganic filler is required to implement a hyperfine pattern. However, although a nanoscale inorganic filler is added, it is still difficult to obtain a homogeneous film through uniform dispersion of the filler.

Therefore, the development of a material of an insulating layer of a printed circuit board with a low CTE is needed. Further, as thinning of a substrate is in progress, a substrate with increased strength and rigidity is needed. The development of a material of an insulating layer which satisfies these two characteristics is needed.

### RELATED ART DOCUMENT

### Patent Document

Patent Document 1: Korean Patent Laid-Open No. 2012-0042422

### SUMMARY OF THE INVENTION

The present invention has been invented in order to overcome the above-described problems and it is, therefore, an object of the present invention to provide an insulation material having a new structure, which has advantages of insulation, rigidity, and heat resistance by incorporating polysilsesquioxane (hereinafter, referred to as “POSS”) and derivatives thereof into a main chain of a soluble liquid crystal thermosetting polymer having a low coefficient of thermal expansion, which is used in an insulating layer of a printed circuit board.

Further, it is another object of the present invention to provide an insulation composition including an insulation material having a new structure.

Further, it is still another object of the present invention to provide a substrate including an insulating prepreg or an insulating film using an insulation composition.

An insulation material having a new structure in accordance with the present invention is a soluble liquid crystal thermosetting oligomer containing POSS having a structure in which the POSS is combined with a main chain of a soluble liquid crystal thermosetting oligomer.

The combination of the POSS and the soluble crystal liquid thermosetting oligomer may be formed by a covalent bond between an unsaturated double bond included in the soluble liquid crystal thermosetting oligomer and a functional group included in the POSS.

The unsaturated double bond included in the soluble liquid crystal thermosetting oligomer may be at least one selected from the group consisting of maleimide, naphtalene acetaimide, phthalimide, acetylene, propagyl ether, benzocyclobutene, cyanate, and substituents or derivatives thereof.

The functional group included in the POSS may be at least one selected from the group consisting of a methacrylic group, a vinyl group, a mercapto group, a norbornyl group, a styryl group, an olefin group, and combinations thereof.

The POSS may be included in the chain of the soluble liquid crystal thermosetting oligomer in an amount of 3 to 85 wt %.

It is preferred that the soluble liquid crystal thermosetting oligomer is a soluble liquid crystal thermosetting oligomer containing POSS which is a compound represented by Chemical Formula 1.

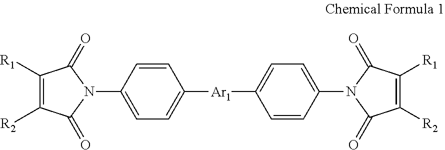

In the above Formula, R₁ and R₂ are CH₃ or H, and at least one of R₁ and R₂ is CH₃,

Ar₁ is a divalent aromatic organic group having a molecular weight of less than 5,000, which includes one or more structural units selected from the group consisting of ester, amide, ester amide, ester imide, and ether imide, and

Ar₁ includes one or more structural units selected from the group represented by Chemical Formula 2.

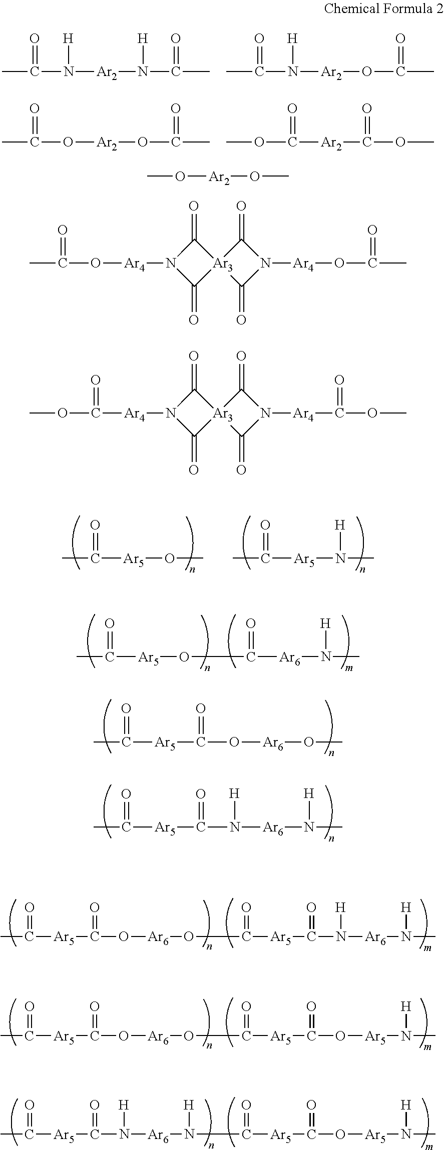

In the above Formula, Ar₂, Ar₄, Ar₅, and Ar₆ are divalent aromatic organic groups and include one or more structural units selected from the group represented by Chemical Formula 3,

Ar₃ is a tetravalent aromatic organic group and includes one or more structural units selected from the group represented by Chemical Formula 4, and

n and m are integers from 1 to 100.

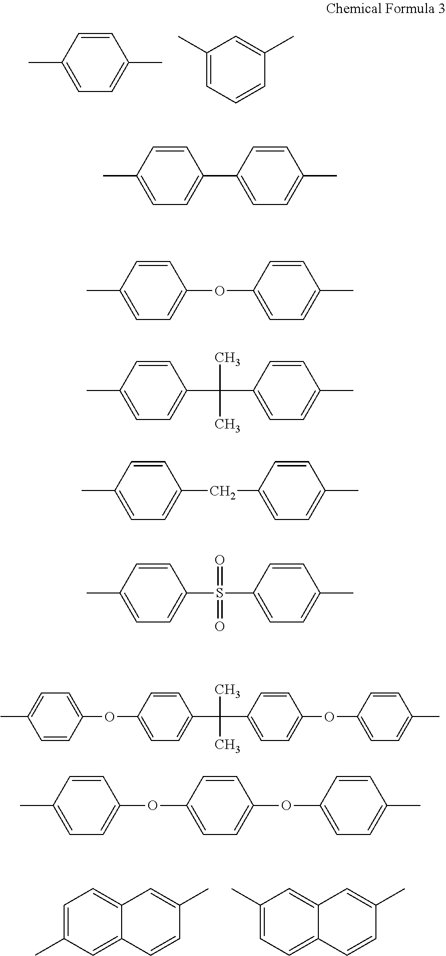

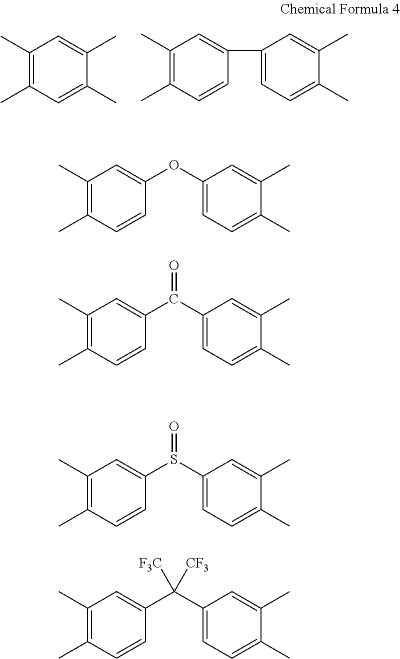

A number average molecular weight of the soluble liquid crystal thermosetting oligomer is 500 to 15,000.

Further, an insulation composition in accordance with the present invention may include a soluble liquid crystal thermosetting oligomer containing POSS, a graphene oxide, and a short fiber.

The graphene oxide may have at least one functional group selected from a hydroxyl group, a carboxyl group, and an epoxy group on its surface and edge.

It is preferred that the graphene oxide has a ratio of carbon atoms to oxygen atoms (carbon/oxygen ratio) of 1 to 20.

The short fiber may have a fiber length of 50 μm to 10 mm.

For a concrete example, the short fiber may be at least one selected from the group consisting of a glass fiber, Kevlar, a carbon fiber, and alumina.

The composition may include 0.01 to 80 parts by weight of the graphene oxide and 0.01 to 50 parts by weight of the short fiber based on 100 parts by weight of the soluble liquid crystal thermosetting oligomer containing POSS.

Further, according to an embodiment of the present invention, the soluble liquid crystal thermosetting oligomer may additionally include an epoxy resin in its main chain.

The epoxy resin may be included in an amount of 0.01 to 50 parts by weight based on 100 parts by weight of the soluble liquid crystal thermosetting oligomer.

The soluble liquid crystal thermosetting oligomer and the graphene oxide may have an organic/inorganic hybrid structure by forming a covalent bond with each other through a curing reaction.

The present invention may provide an insulating prepreg or an insulating film using the insulation composition.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

These and/or other aspects and advantages of the present general inventive concept will become apparent and more readily appreciated from the following description of the embodiments, taken in conjunction with the accompanying drawings of which:

FIG. 1 shows a portion of a typical printed circuit board structure;

FIG. 2 shows a prepreg type insulating layer for a printed circuit board;

FIG. 3 shows a film type insulating layer for a printed circuit board;

FIG. 4 is a conceptual diagram showing the state in which an inorganic filler is added to an epoxy matrix in accordance with the prior art;

FIG. 5 shows a structure in which a soluble liquid crystal thermosetting oligomer and POSS are combined with each other in accordance with the present invention;

FIG. 6 shows a structure of a graphene oxide in accordance with the present invention; and

FIG. 7 is a conceptual diagram of a process of impregnating an insulation composition in a glass fabric in accordance with an embodiment of the present invention.

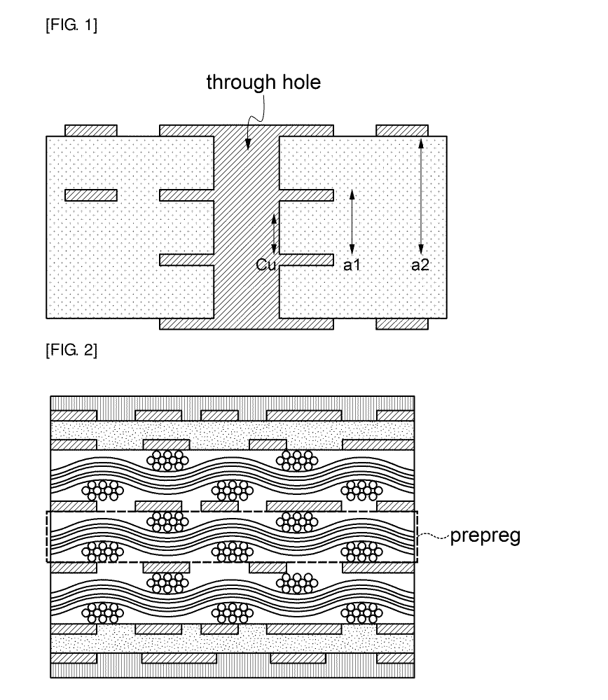

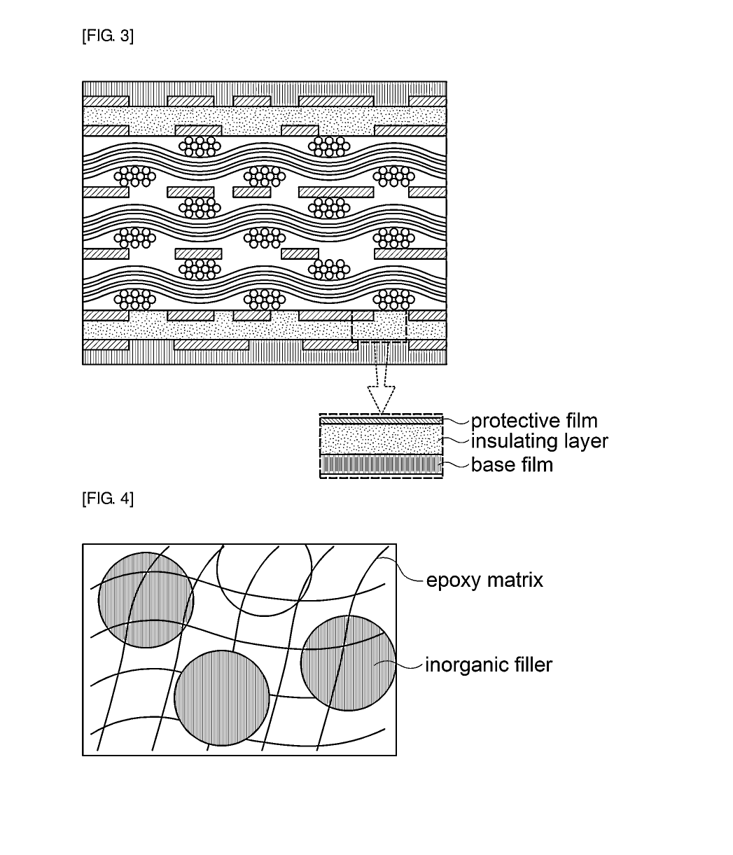

### DETAILED DESCRIPTION OF THE PREFERABLE EMBODIMENTS

Hereinafter, the present invention will be described in detail.

Terms used herein are provided to explain embodiments, not limiting the present invention. Throughout this specification, the singular form includes the plural form unless the context clearly indicates otherwise. Further, terms “comprises” and/or “comprising” used herein specify the existence of described shapes, numbers, steps, operations, members, elements, and/or groups thereof, but do not preclude the existence or addition of one or more other shapes, numbers, operations, members, elements, and/or groups thereof.

The present invention relates to an insulation material having a new structure which can be used in an insulation composition, an insulation composition comprising the same, and a substrate having a high rigidity and a low coefficient of thermal expansion, which includes the insulation composition as an insulating layer.

The insulation material having a new structure in accordance with the present invention is a soluble liquid crystal thermosetting oligomer containing polysilsesquioxane (POSS) having a structure in which POSS is combined with a main chain of a soluble liquid crystal thermosetting oligomer.

The present invention may provide a hybrid insulation material in which POSS is incorporated into a main chain of a soluble liquid crystal thermosetting oligomer having excellent thermal (CTE), electrical, and mechanical stabilities or a soluble liquid crystal thermosetting oligomer containing an epoxy resin in its main chain.

A polymer according to the present invention may be a soluble liquid crystal thermosetting oligomer having excellent thermal (CTE), electrical, and mechanical stabilities or a soluble liquid crystal thermosetting oligomer prepared by adding a small amount of epoxy to a main chain of the above soluble liquid crystal thermosetting oligomer.

This soluble liquid crystal thermosetting oligomer of the present invention may be represented by Chemical Formula 1.

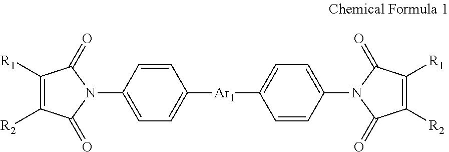

In the above Formula, R₁ and R₂ are CH₃ or H, and at least one of R₁ and R₂ is CH₃,

Ar₁ is a divalent aromatic organic group having a molecular weight of less than 5,000, which includes one or more structural units selected from the group consisting of ester, amide, ester amide, ester imide, and ether imide, and

Ar₁ includes one or more structural units selected from the group represented by Chemical Formula 2.

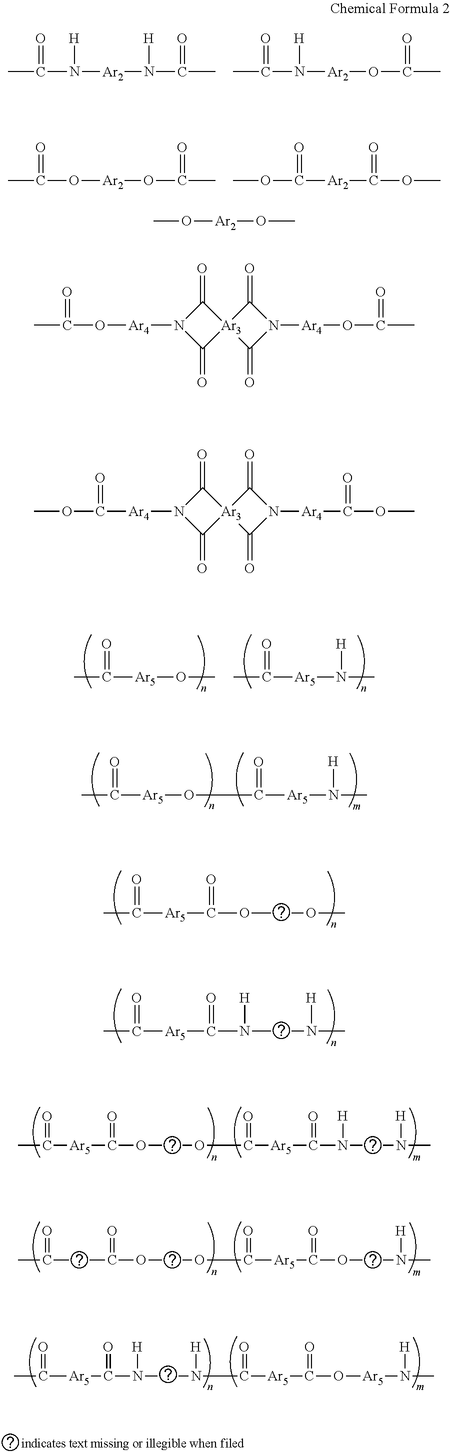

In the above Formula, Ar₂, Ar₄, Ar₅, and Ar₆ are divalent aromatic organic groups and include one or more structural units selected from the group represented by Chemical Formula 3,

Ar₃ is a tetravalent aromatic organic group and includes one or more structural units selected from the group represented by Chemical Formula 4, and

n and m are integers from 1 to 100.

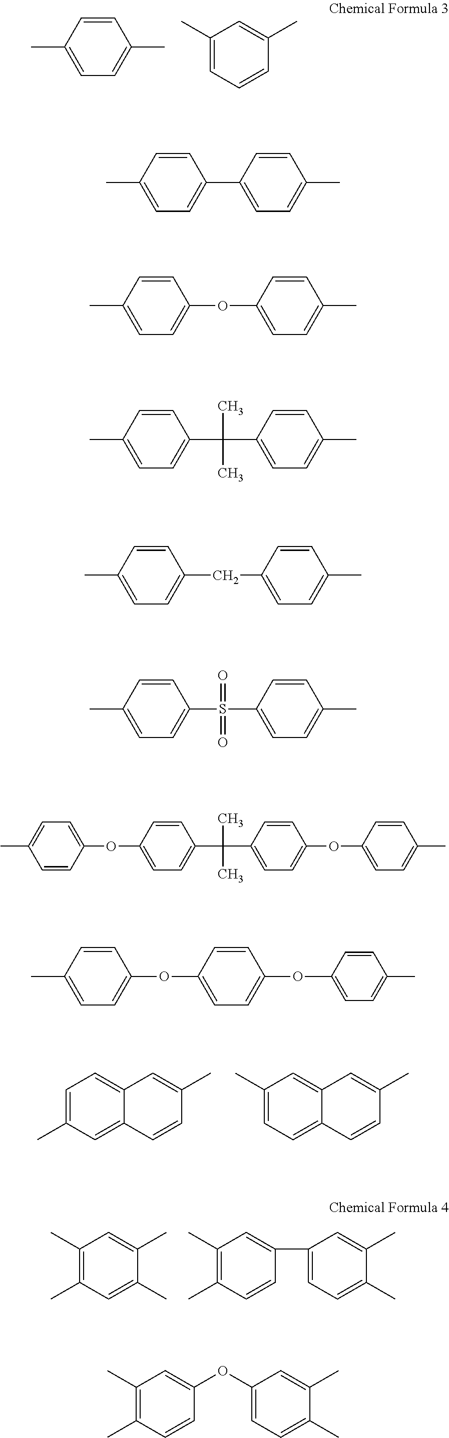

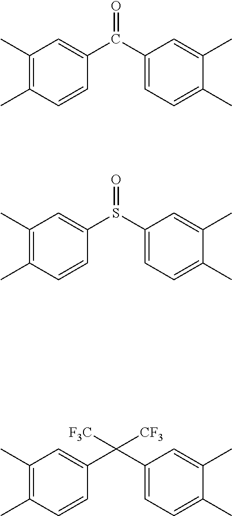

It is preferred that a number average molecular weight of the soluble liquid crystal thermosetting oligomer represented by Chemical Formula 1 is 500 to 15,000. When the molecular weight of the soluble liquid crystal thermosetting oligomer is less than 500, physical properties may be brittle due to an increase in crosslinking density, and when the molecular weight of the soluble liquid crystal thermosetting oligomer exceeds 15,000, it may be disadvantageous when being impregnated into a glass fiber non-woven fabric due to an increase in viscosity of the solution.

Further, the soluble liquid crystal thermosetting oligomer represented by Chemical Formula 1 includes at least one unsaturated double bond selected from the group consisting of maleimide, naphthalene acetaimide, phthalimide, acetylene, propagyl ether, benzocyclobutene, cyanate, and substituents or derivatives thereof. The unsaturated double bond forms a covalent bond with a functional group of POSS later to be combined as an insulation material having a hybrid structure.

Further, in an insulation composition, the unsaturated double bond may be combined with various functional groups on the surface of a graphene oxide to form an organic/inorganic hybrid structure.

Further, the polymer resin according to the present invention may be a soluble liquid crystal thermosetting oligomer prepared by adding an epoxy resin to the main chain of the above soluble liquid crystal thermosetting oligomer.

At this time, the epoxy resin may be included in an amount of 0.01 to 50 parts by weight based on 100 parts by weight of the soluble liquid crystal thermosetting oligomer. Further, the epoxy resin used is not particularly limited. For example, the epoxy resin may be a bisphenol-A type epoxy resin, a naphthalene-modified epoxy resin, a cresol novolac epoxy resin, a rubber-modified epoxy resin, etc. It is possible to use these materials independently or by mixing at least two of them, but it is not particularly limited thereto.

An example of the soluble liquid crystal thermosetting oligomer according to the present invention is shown in Chemical Formula 5.

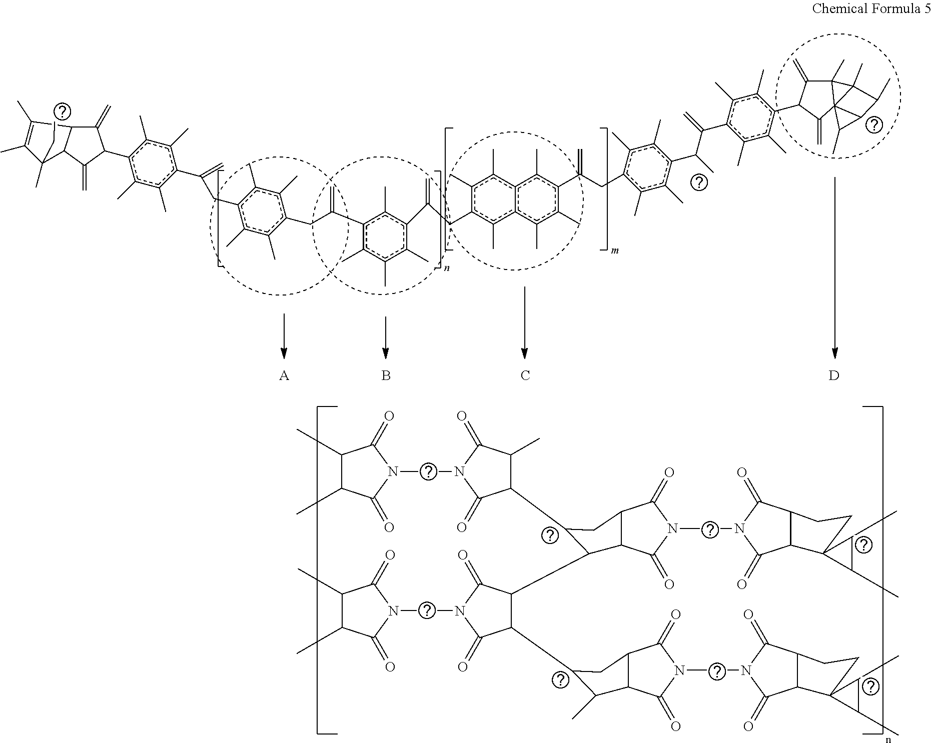

As in Chemical Formula 5, the soluble liquid crystal thermosetting oligomer according to the present invention is characterized by including a soluble structure A, which can be dissolved in one or more solvents, and a group B with excellent proccessability in the main chain thereof to be dissolved in common solvents and by having thermally curable functional groups D at both ends thereof as well as a functional group C which can implement liquid crystal properties.

Methods of preparing the soluble liquid crystal thermosetting oligomer according to the present invention are not particularly limited. The soluble liquid crystal thermosetting oligomer may be prepared by reacting compounds which can prepare a liquid crystal oligomer including a soluble structural unit through polymerization and compounds which can incorporate a thermosetting group.

The compounds which can prepare a liquid crystal oligomer including a soluble structural unit are not particularly limited. For example, the compounds may be selected from the group consisting of one or more aromatic, heteroaromatic, or aliphatic dicarboxylic acids; aromatic, hetoroaromatic, or aliphatic diols; aromatic, heteroaromatic, or aliphatic diamines; aminophenols; hydroxybenzoic acids; and aminobenzoic acids, preferably one or more of aromatic, heteroaromatic, or aliphatic diols; aminophenols; and aminobenzoic acids.

For example, the liquid crystal thermosetting oligomer may be prepared by solution polymerization or bulk polymerization. The solution polymerization and the bulk polymerization may be performed in one reaction tank provided with a suitable stirring means.

Since the soluble liquid crystal thermosetting oligomer having the above structure has a much lower coefficient of thermal expansion than the epoxy resin used as an insulating polymer in the past and includes various functional groups, it is advantageous in forming a hybrid composite structure with other components included in the insulation composition.

Further, the insulation material having a hybrid structure according to the present invention is prepared by incorporating POSS represented by Chemical Formula 6 and derivatives thereof in the main chain of the above soluble liquid crystal thermosetting oligomer.

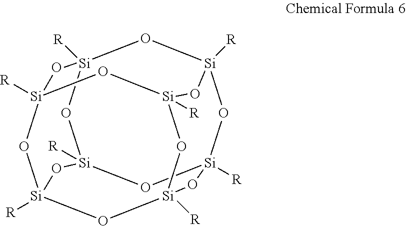

In the above Formula, R is hydrogen, a methacrylic group, a vinyl group, a mercapto group, a norbornyl group, a styryl group, an olefin group, or an acrylic group, and n is 8, 10, 12, or 16.

In polysilsesquioxane, silsesquioxane having a cage structure is called polyhedral oligomeric silsesquioxane (POSS) and can be represented by (RSiO_{1.5})n.

The POSS is first synthesized in 1946 and generally obtained by hydrolysis-condensation of RSiX₃ (X is Cl or an alkoxy group) which is a trifunctional group. Polysilsesquioxane having a ladder structure is excellent in heat resistance and particularly stable during oxidation at a high temperature over 500° C.

The POSS according to the present invention may include at least one functional group selected from the group consisting of a methacrylic group, a vinyl group, a mercapto group, a norbornyl group, a styryl group, an olefin group, an acrylic group, and combinations thereof.

For a concrete example, the POSS including a functional group may be represented by Chemical Formulas 7 to 10. Chemical Formula 7 represents a structure of styryl-POSS.

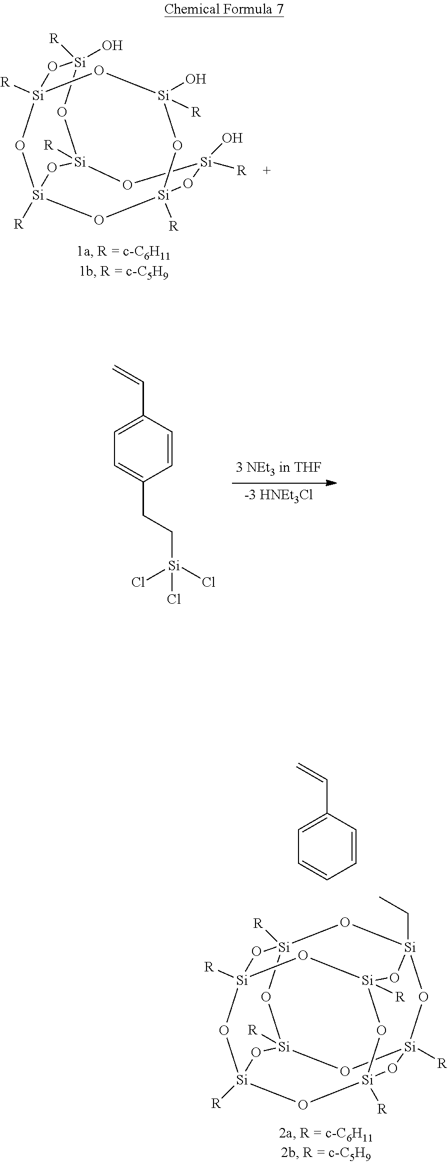

Chemical Formula 8 represents structures of POSS which include a norbornyl group and a vinyl group, respectively.

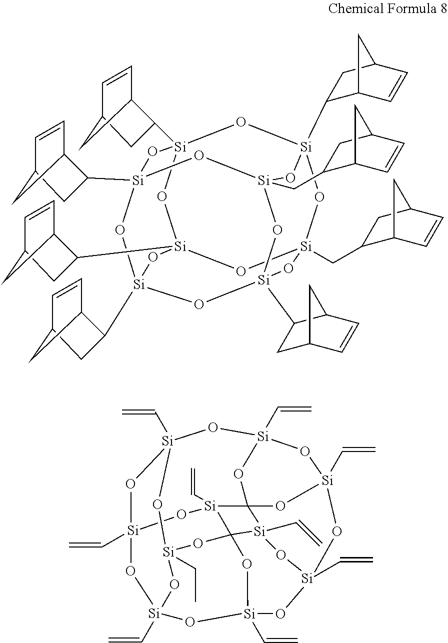 [SMILES: C1=CC2CC1CC2C[Si]12O[Si]3(C4CC5C=CC4C5)O[Si]4(CC5CC6C=CC5C6)O[Si](C5CC6C=CC5C6)(O1)O[Si]1(C5CC6C=CC5C6)O[Si](C5CC6C=CC5C6)(O2)O[Si](C2CC5C=CC2C5)(O3)O[Si](C2CC3C=CC2C3)(O4)O1 ; C=C[Si]12OC34O[Si](C=C)(O1)O[Si]1(C=C)O[Si]5(C=C)OC6(O[Si]7(CC)O[Si](C=C)(O2)O[Si](C=C)(O[Si](C=C)(O5)O7)O[Si]36C=C)[Si]4(C=C)O1]

Chemical Formula 9 represents structures of POSS which include a norbornyl group, an olefin group, a styryl group, and an acrylic group, respectively.

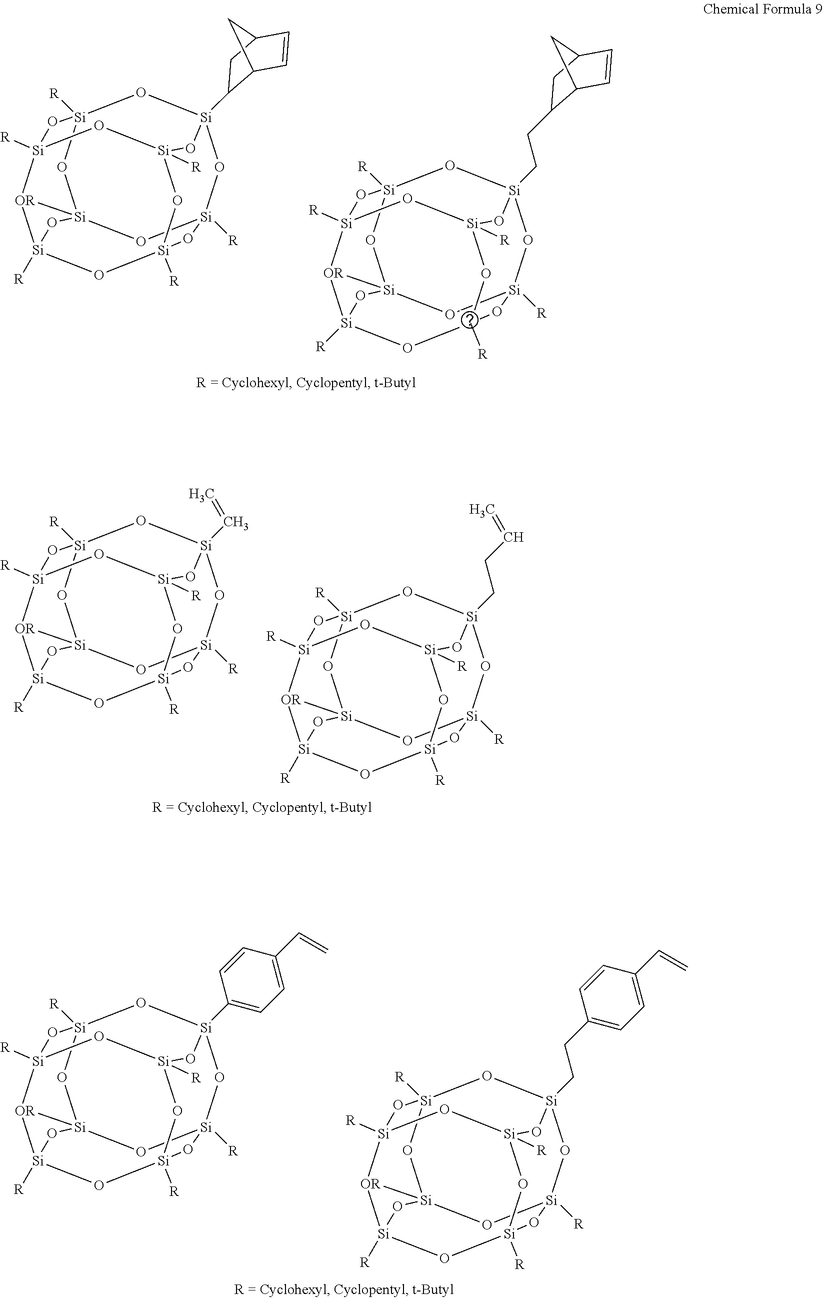

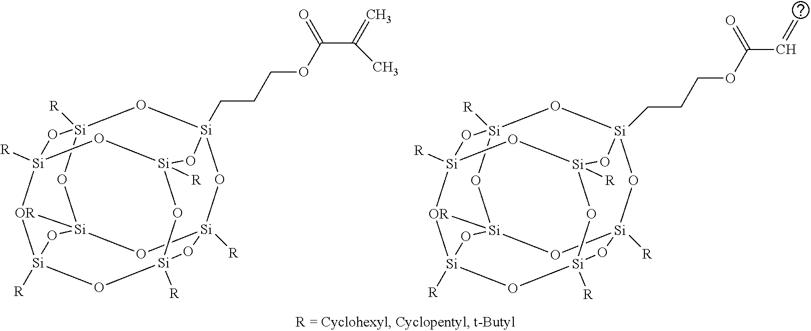

Chemical Formula 10 represents a structure of POSS including a mercapto group.

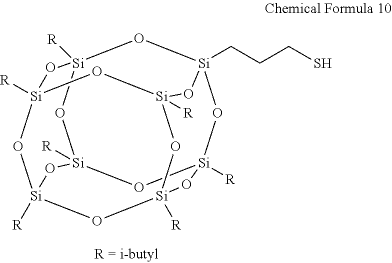

The insulation material having a hybrid structure according to the present invention may be formed by a covalent bond between the unsaturated double bond of the soluble liquid crystal thermosetting oligomer represented by Chemical Formula 1 and the functional group included in the POSS.

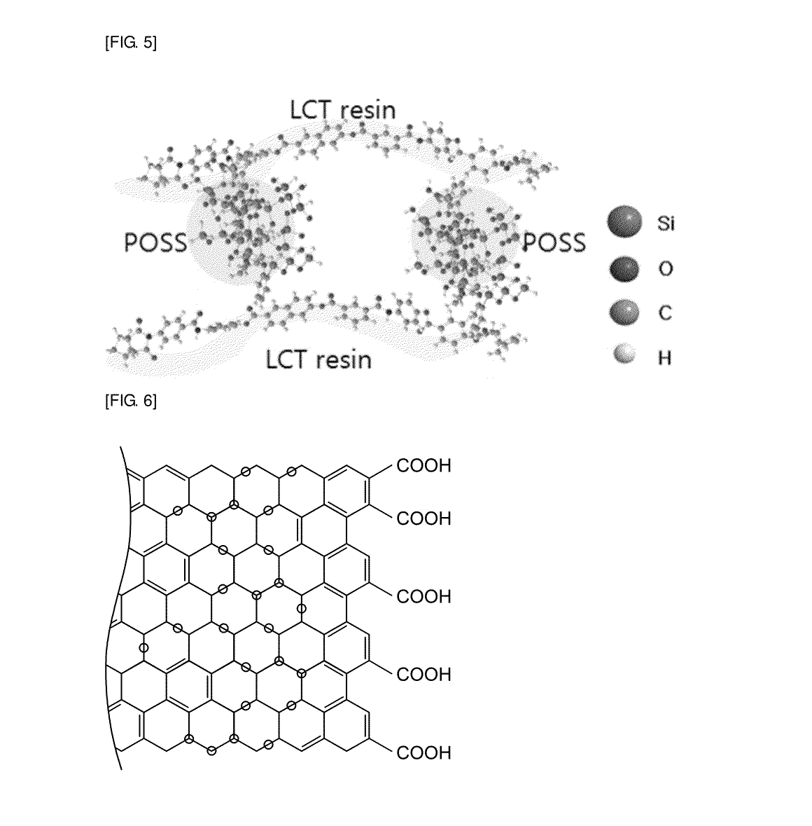

Therefore, as in FIG. 5, it is possible to form an LCT+POSS cluster nanocomposite material covalently bonded with the soluble liquid crystal thermosetting oligomer.

The POSS may be included in an amount of 3 to 85 wt % in the main chain of the soluble liquid crystal thermosetting oligomer.

It is possible to achieve improvements in polymer properties such as increase in use temperature, oxidation resistance, surface hardening, and improved mechanical properties by incorporating the POSS and derivatives thereof in the main chain of the soluble liquid crystal thermosetting oligomer. Further, it is possible to reduce viscosity as well as flammability and heat evolution.

The reaction of incorporating the POSS into the main chain of the soluble liquid crystal thermosetting oligomer may form a crosslinking structure by Michael reaction which reacts with a carbon-carbon double bond.

Further, the present invention may provide an insulation composition including a soluble liquid crystal thermosetting oligomer containing POSS, a graphene oxide, and a short fiber.

The graphene oxide is characterized by a low coefficient of thermal expansion and excellent mechanical characteristics. Therefore, it is possible to improve characteristics of a polymer resin only by adding a smaller amount of the graphene oxide than an inorganic filler such as silica, which is generally added to improve mechanical strength of the polymer resin.

The graphene oxide may be prepared by oxidizing graphite. The graphite has a layered structure in which graphene having a plate structure formed by connecting carbon atoms in a hexagonal ring is stacked. Generally, since the graphite has a structure in which the distance between the layers is 3.35 Å and carbon nanotubes are spread in a plate state, the graphite has high conductivity corresponding to the carbon nanotube and excellent mechanical properties.

When graphite powder is oxidized, graphene oxide powder, which has at least one functional group of a hydroxyl group, a carboxyl group, and an epoxy group attached to its surface and edge while maintaining a layered structure, is obtained by oxidizing each layer of the graphite.

The graphene oxide powder may be prepared by oxidizing the graphite powder by an oxidizing agent or an electrochemical method. The oxidizing agent is not limited to the following, but for example, nitric acid, NaClO₃, KMnO₄, etc. may be used as the oxidizing agent, and one or a mixture of two or more of them may be used as the oxidizing agent.

It is preferred that the graphene oxide according to the present invention is sufficiently oxidized not to deteriorate the insulating properties of the polymer resin. That is, it is preferred that the graphene oxide according to the present invention is sufficiently oxidized to hardly exhibit electrical conductivity characteristics or completely lose the electrical conductivity characteristics. For this, it is preferred that a ratio (carbon/oxygen) of carbon atoms to oxygen atoms of the graphene oxide may change according to the degree of oxidization, for example, preferably 1 to 20.

FIG. 6 schematically shows a portion of the structure of the graphene oxide in accordance with the present invention. The graphene oxide includes a plurality of functional groups such as hydroxyl groups, epoxy groups, and carboxyl groups on its surface and edge. The type and number of the functional groups may be different according to oxidization methods or the degree of oxidization.

Therefore, when the graphene oxide is added to the insulation composition of the present invention, the graphene oxide can be physically dispersed in the cured product of the soluble liquid crystal thermosetting oligomer resin. Further, the graphene oxide having functional groups can form a covalent bond with the unsaturated double bond included in the soluble liquid crystal thermosetting oligomer by curing reaction, thus becoming a composite which is organically connected to the soluble liquid crystal thermosetting oligomer resin.

It is preferred that the graphene oxide is included in an amount of 0.01 to 50 parts by weight based on the weight of the soluble liquid crystal thermosetting oligomer. When the content of the graphene oxide is less than 0.01 parts by weight, the effect of reducing the coefficient of thermal expansion is small. Further, when the content of the graphene oxide exceeds 50 parts by weight, viscosity becomes lower, resulting in a very small thickness.

In the insulation composition according to the present invention, when a curing reaction is performed by adding a hardener to the soluble liquid crystal thermosetting oligomer or the soluble liquid crystal thermosetting oligomer including an epoxy resin in its main chain, the POSS, and the graphene oxide, soluble liquid crystal thermosetting oligomer-POSS, epoxy-POSS, and POSS-POSS hybrid curing reactions or covalent bond reactions as well as curing of the soluble liquid crystal thermosetting oligomer and the epoxy resin occur, thus forming a composite material in which the soluble liquid crystal thermosetting oligomer and the POSS are organically connected to each other.

Further, the insulation composition according to the present invention includes the short fiber to improve strength and rigidity of an insulating layer.

The short fiber according to the present invention means a short fiber with a fiber length of 50 μm to 10 mm. When the length of the short fiber is less than 50 μm, it is not preferred since improvement of mechanical properties is slight due to a low slenderness ratio. Further, when the length of the short fiber exceeds 10 mm, it is not preferred since a reinforcing effect doesn't occur properly due to a difficulty in mixing and non-uniform distribution of the short fiber when dispersing the short fiber in the insulating polymer resin.

The short fiber may be at least one selected from the group consisting of a glass fiber, kevlar, a carbon fiber, and alumina.

It is preferred that the short fiber is included in an amount of 0.01 to 50 parts by weight based on the weight of the soluble liquid crystal thermosetting oligomer. When the content of the short fiber is less than 0.01 parts by weight, a mechanical reinforcing effect doesn't occur. Further, when exceeding 50 parts by weight, it is not preferred since several problems may occur when processing a substrate due to a difficulty in dispersion.

Further, a solvent used when preparing the insulation composition in accordance with the present invention is not particularly limited. For example, the solvent may be selected from the group consisting of N,N-dimethylacetamide, N-methylpyrrolidone (NMP), N-methylcaprolactone, N,N-dimethylformamide, N,N-diethylformamide, N,N-diethylacetamide, N-methylpropionamide, dimethylsulfoxide, gamma-butyllactone, dimethylimidazolidinone, tetramethylphosphoric amide, and ethylcellosolve acetate, and the mixed solvent of two or more of them can be selectively used.

The insulation composition of the present invention may further include one or more additives such as a filler, a softener, a plasticizer, a lubricant, an antistatic agent, a coloring agent, an antioxidant, a heat stabilizer, a light stabilizer, and a UV absorber when necessary.

Examples of the filler may include organic fillers such as epoxy resin powder, melamine resin powder, urea resin powder, benzoguanamine resin powder, and styrene resin; and inorganic fillers such as silica, alumina, titanium oxide, zirconia, kaolin, calcium carbonate, and calcium phosphate.

The present invention may provide an insulating prepreg or an insulating film using the above insulation composition. According to the present invention, the insulation composition may be impregnated in a woven glass cloth to be formed into a prepreg or the insulation composition itself may be formed into a build-up film.

Further, the present invention may provide a substrate including the above insulating prepreg or insulating film.

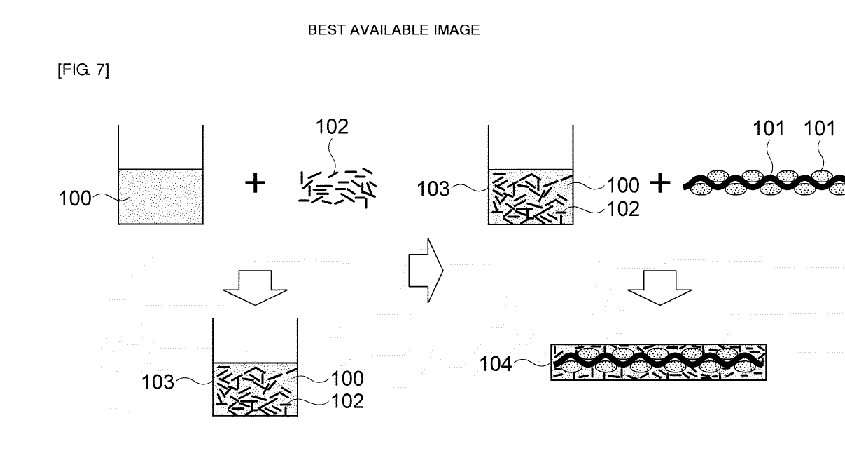

In the insulation composition according to the present invention, a short fiber-dispersed insulating resin 103 is prepared by adding a short fiber 102 to a solution 100 prepared by mixing a soluble liquid crystal thermosetting resin (LCT resin), a graphene oxide, and POSS as in FIG. 7.

Next, a prepreg 104, which is a short fiber-reinforced insulation material, is prepared by impregnating the insulating resin in an appropriate reinforcing agent 101. The reinforcing agent used at this time is not particularly limited, but for example, the reinforcing agent may be woven glass cloth, woven alumina glass cloth, nonwoven glass fabric, nonwoven cellulose fabric, woven carbon cloth, or polymer cloth. Further, a method of impregnating the insulation composition in the reinforcing agent may be dip coating, roll coating, etc, and other typical impregnation methods may be used.

Continuously, the prepreg is dried at appropriate temperature and time, laid up with a copper foil etc, and cured to be formed into a sheet.

Further, since the insulation composition according to the present invention has high adhesive strength to the copper foil and exhibits high heat resistance, low expansion, and excellent mechanical properties, it can be used as an excellent packaging material. The insulation composition can be formed into a substrate or a varnish for impregnation or coating. The composition can be applied to a printed circuit board, each layer of a multilayer substrate, a copper clad laminate (for example, RCC, CLL), and a TAB film, but the purpose of the insulation composition is not limited thereto.

According to the present invention, it is possible to effectively reduce a coefficient of thermal expansion by including a material having a hybrid structure, which is obtained by incorporating POSS and derivatives thereof into a main chain of a soluble liquid crystal thermosetting oligomer, in an insulation composition.

Further, it is possible to manufacture a substrate with improved thermal stability by using an insulation composition as an insulation material of the substrate to minimize dimensional deformation due to heat.

What is claimed is:

1. An insulation material having a structure in which polysilsesquioxane (POSS) is combined with a main chain of a soluble liquid crystal thermosetting oligomer.

2. The insulation material according to claim 1, wherein the combination of the POSS and the soluble crystal liquid thermosetting oligomer is formed by a covalent bond between an unsaturated double bond included in the soluble liquid crystal thermosetting oligomer and a functional group included in the POSS.

3. The insulation material according to claim 2, wherein the unsaturated double bond included in the soluble liquid crystal thermosetting oligomer is at least one selected from the group consisting of maleimide, naphtalene acetaimide, phthalimide, acetylene, propagyl ether, benzocyclobutene, cyanate, and substituents or derivatives thereof.

4. The insulation material according to claim 2, wherein the functional group included in the POSS is at least one selected from the group consisting of a methacrylic group, a vinyl group, a mercapto group, a norbornyl group, a styryl group, an olefin group, and combinations thereof.

5. The insulation material according to claim 1, wherein the POSS is included in the chain of the soluble liquid crystal thermosetting oligomer in an amount of 3 to 85 wt %.

6. The insulation material according to claim 1, wherein the soluble liquid crystal thermosetting oligomer is a compound represented by Chemical Formula 1: 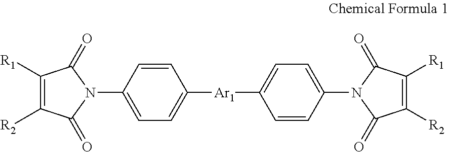
where R₁ and R₂ are CH₃ or H, and at least one of R₁ and R₂ is CH₃,
Ar₁ is a divalent aromatic organic group having a molecular weight of less than 5,000, which includes one or more structural units selected from the group consisting of ester, amide, ester amide, ester imide, and ether imide, and
Ar₁ includes one or more structural units selected from the group represented by Chemical Formula 2: 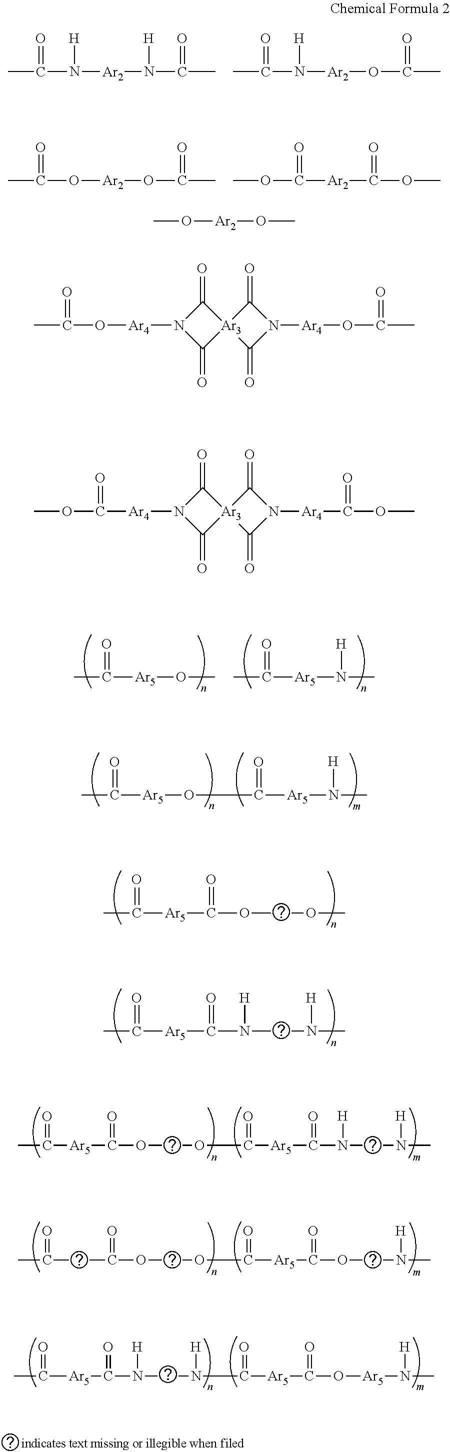
where Ar₂, Ar₄, Ar₅, and Ar₆ are divalent aromatic organic groups and include one or more structural units selected from the group represented by Chemical Formula 3,
Ar₃ is a tetravalent aromatic organic group and includes one or more structural units selected from the group represented by Chemical Formula 4, and
n and m are integers from 1 to 100.

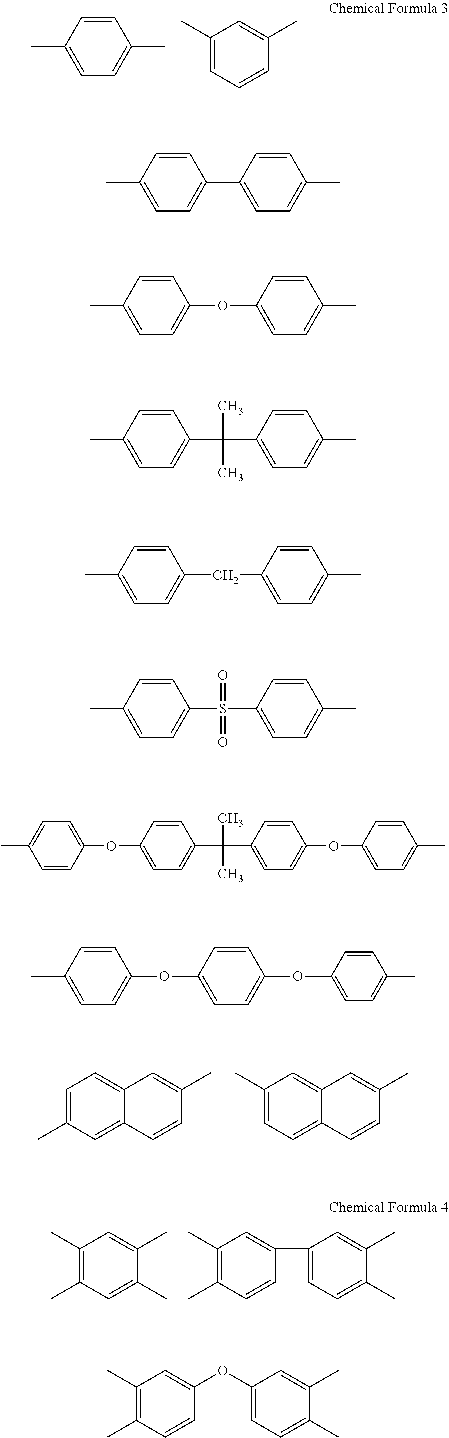

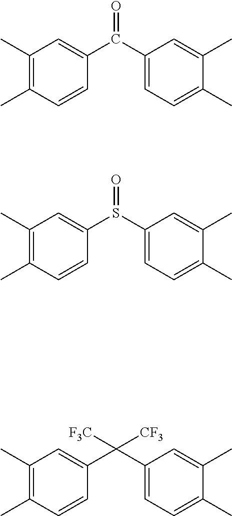

7. The insulation material according to claim 1, wherein a number average molecular weight of the soluble liquid crystal thermosetting oligomer is 500 to 15,000.

8. A substrate insulating layer composition comprising a soluble liquid crystal thermosetting oligomer containing POSS according to claim 1, a graphene oxide, and a short fiber.

9. The substrate insulating layer composition according to claim 8, wherein the graphene oxide has at least one functional group selected from a hydroxyl group, a carboxyl group, and an epoxy group on its surface and edge.

10. The substrate insulating layer composition according to claim 8, wherein the graphene oxide has a ratio of carbon atoms to oxygen atoms (carbon/oxygen ratio) of 1 to 20.

11. The substrate insulating layer composition according to claim 8, wherein the short fiber has a fiber length of 50 μm to 10 mm.

12. The substrate insulating layer composition according to claim 8, wherein the short fiber is at least one selected from the group consisting of a glass fiber, Kevlar, a carbon fiber, and alumina.

13. The substrate insulating layer composition according to claim 8, wherein the composition includes 0.01 to 80 parts by weight of the graphene oxide and 0.01 to 50 parts by weight of the short fiber based on 100 parts by weight of the soluble liquid crystal thermosetting oligomer containing POSS.

14. The substrate insulating layer composition according to claim 8, wherein the soluble liquid crystal thermosetting oligomer further includes an epoxy resin in its main chain.

15. The substrate insulating layer composition according to claim 14, wherein the epoxy resin is included in an amount of 0.01 to 50 parts by weight based on 100 parts by weight of the soluble liquid crystal thermosetting oligomer.

16. The substrate insulating layer composition according to claim 8, wherein the soluble liquid crystal thermosetting oligomer and the graphene oxide have an organic/inorganic hybrid structure by forming a covalent bond with each other through a curing reaction.

17. An insulating prepreg or an insulating film using an insulation composition according to claim 8.

18. A substrate comprising an insulating prepreg or an insulating film according to claim 17.
